(19) United States
(12) Patent Application Publication
(10) Pub. No.: US 2016/0149029 A1
(43) Pub. Date: May 26, 2016

(54) SEMICONDUCTOR DEVICE AND METHOD FOR MANUFACTURING SEMICONDUCTOR DEVICE

(71) Applicant: TOYOTA JIDOSHA KABUSHIKI KAISHA, Toyota-shi (JP)

(72) Inventors: Hidefumi TAKAYA, Toyota-shi (JP); Katsuhiro KUTSUKI, Nagakute-shi (JP); Sachiko AOI, Nagakute-shi (JP); Shinichiro MIYAHARA, Nagoya-shi (JP)

(21) Appl. No.: 14/939,720

(22) Filed: Nov. 12, 2015

(30) Foreign Application Priority Data
Nov. 21, 2014 (JP) 2014-236545

(51) Int. Cl. H01L 29/78; H01L 29/06; H01L 21/28; H01L 21/225; H01L 21/306; H01L 29/66; H01L 29/10

(52) U.S. Cl. CPC H01L 29/7813; H01L 29/66734; H01L 29/0696; H01L 29/1095; H01L 29/1045; H01L 21/2253; H01L 21/30604; H01L 21/28008

(57) ABSTRACT

A semiconductor device includes a semiconductor substrate including a trench, a gate insulating layer, and a gate electrode. A step is arranged in a side surface of the trench. The semiconductor substrate includes first and second regions, a body region, and a side region. The body region extends from a position being in contact with the first region to a position located on the lower side with respect to the step. The body region is in contact with the gate insulating layer at a portion of the upper side surface located on a lower side with respect to the first region. The second region is located on a lower side of the body region and in contact with the gate insulating layer at the lower side surface. The side region is in contact with the gate insulating layer at the step surface and connected to the second region.

### CROSS-REFERENCE TO RELATED APPLICATION

This application claims priority to Japanese Patent Application No. 2014-236545 filed on Nov. 21, 2014, the contents of which are hereby incorporated by reference into the present application.

### TECHNICAL FIELD

A technology disclosed herein relates to a semiconductor device having a gate electrode disposed in a trench.

### DESCRIPTION OF RELATED ART

Japanese Patent Application Publication No. 2006-128507 A discloses a MOSFET having a gate electrode disposed in a trench. This MOSFET includes a semiconductor substrate in which an n-type source region, a p-type body region, and an n-type drift region are provided. That is, this MOSFET is of an n-channel type. Application of a predetermined potential to the gate electrode causes a portion of the body region that is adjacent to a gate insulating layer to be inverted into n-type, and a current flows through the region (i.e. a channel) thus inverted into n-type.

### BRIEF SUMMARY

In the MOSFET of Japanese Patent Application Publication No. 2006-128507, a channel length varies according to a thickness of the body region. That is, a reduction in the thickness of the body region leads to a decrease in the channel length, and thus to a reduction in loss that is caused in the MOSFET. Further, the thickness of the body region also affects a punch-through voltage. That is, if a drain voltage is raised while the MOSFET is off, a depletion layer extends from an interface between the body region and the drift region into the body region. Further raising the drain voltage causes the depletion layer to reach the source region. That is, there occurs a phenomenon (so-called punch-through) in which the source region and the drift region are connected to each other via the depletion layer. The occurrence of a punch-through generates a leak current, thus presenting a problem. The drain voltage at the time of occurrence of a punch-through is the punch-through voltage. The greater the thickness of the body region, the higher the punch-through voltage becomes (i.e. the punch-through voltage is improved). That is, while it is necessary to make the thickness of the body region thinner in order to make the channel length shorter, it is necessary to make the thickness of the body region greater in order to make the punch-through voltage higher. In this way, there has conventionally been a trade-off between the channel length and the punch-through voltage. Such a trade-off also occurs in various types of semiconductor devices having gate electrodes, such as p-channel MOSFETs and IGBTs. Therefore, the present specification provides a technology that makes it possible to improve such a trade-off relationship.

A semiconductor device disclosed herein comprises a semiconductor substrate that comprises a surface and a trench in the surface; a gate insulating layer covering an inner surface of the trench; and a gate electrode located in the trench. A step is arranged in a side surface of the trench. The side surface of the trench includes an upper side surface located on an upper side with respect to the step, a step surface which is a surface of the step, and a lower side surface located on a lower side with respect to the step. The semiconductor substrate comprises a first region, a body region, a second region, and a side region. The first region is of a first conductivity type and in contact with the gate insulating layer at the upper side surface. The body region is of a second conductivity type, extending from a position being in contact with the first region to a position located on the lower side with respect to the step, and in contact with the gate insulating layer at a portion of the upper side surface that is located on a lower side with respect to the first region. The second region is of the first conductivity type, located on a lower side of the body region, and in contact with the gate insulating layer at the lower side surface. The side region is of the first conductivity type, in contact with the gate insulating layer at the step surface, and connected to the second region.

The term “upper side” used herein means a side of the surface of the semiconductor substrate in which the trench is formed. A term “lower side” as used herein means a side of a surface opposite to the surface of the semiconductor substrate in which the trench is formed.

In this semiconductor device, the step is arranged in the side surface of the trench, and the side region of the first conductivity type is provided at a position of the step. The side region is connected to the second region located on the lower side of the body region. Since the body region has its lower end located on a lower side with respect to the step, the side region is disposed to protrude upward from the second region. This semiconductor device performs switching through formation of a channel in the body region between the first region and the side region. That is, the channel length is determined by a distance from the first region to the side region. Since the side region protrudes toward an upper side with respect to the lower end of the body region, the channel length is shorter than the thickness of the body region (i.e. the distance from the lower end of the body region to the first region). That is, in this semiconductor device, the channel length can be set to a value smaller than a value of the thickness of the body region. Further, tuning off this semiconductor device causes a depletion layer to extend from an interface between the second region and the body region into the body region. Therefore, the punch-through voltage is determined by the thickness of the body region (i.e. the distance from the lower end of the body region to the first region). As noted above, the thickness of the body region is longer than the channel length. That is, the punch-through voltage can be improved independently of the channel length. As described above, this semiconductor device makes it possible to overcome the conventional trade-off between the channel length and the punch-through voltage and improve both the channel length and the punch-through voltage. For example, in a case where the channel length is set to the same value as that to which it has conventionally been set, the punch-through voltage can be made higher than it has conventionally been. Further, for example, in a case where the punch-through voltage is set to the same value as that to which it has conventionally been set, the channel length can be made shorter than it has conventionally been.

Further, a method for manufacturing a semiconductor device is herein provided. In this method, a semiconductor substrate is prepared. The semiconductor substrate comprises a second region being of a first conductivity type, and a body region being of a second conductivity type and located on an upper side of the second region. In this method, the following processes are performed. A trench is formed in the semiconductor substrate such that the trench penetrates the body region so as to reach the second region and includes a side surface in which a step is formed at a position located on an upper side with respect to the second region. Impurities of the first conductivity type are implanted to a step surface which is a surface of the step so as to form a side region being of the first conductivity type, exposed on the step surface, and connected to the second region. A gate insulating layer covering an inner surface of the trench is formed. A gate electrode is formed in the trench. A first region being of the first conductivity type is formed in the semiconductor substrate. In the manufactured semiconductor device, the first region is in contact with the gate insulating layer at a portion of the side surface that is located on an upper side with respect to the step.

This method makes it possible to manufacture a semiconductor device including a side region.

### BRIEF DESCRIPTION OF DRAWINGS

FIG. 1 is a longitudinal sectional view of a semiconductor device 10 according to Embodiment 1;

FIG. 2 is a longitudinal sectional view of a semiconductor substrate 12 in which an upper region 26b and a lower region 26c have been formed;

FIG. 3 is a longitudinal sectional view of the semiconductor substrate 12 in which trenches 34 have been formed;

FIG. 4 is a longitudinal sectional view of the semiconductor substrate 12 into which p-type ions are being implanted;

FIG. 5 is a longitudinal sectional view of the semiconductor substrate 12 in which bottom insulating layers 38a have been formed;

FIG. 6 is a longitudinal sectional view of the semiconductor substrate 12 into which n-type ions are being implanted;

FIG. 7 is a longitudinal sectional view of the semiconductor substrate 12 in which side insulating layers 38b and gate electrodes 40 have been formed;

FIG. 8 is a longitudinal sectional view of the semiconductor substrate 12 in which source regions 22 and a high-concentration region 26a have been formed;

FIG. 9 is a longitudinal sectional view of a semiconductor device according to Embodiment 2;

FIG. 10 is a longitudinal sectional view of a semiconductor device according to Embodiment 3;

FIG. 11 is a longitudinal sectional view of a semiconductor substrate 12 in which a low-concentration region 26d has been formed;

FIG. 12 is a longitudinal sectional view of the semiconductor substrate 12 in which trenches 134 have been formed;

FIG. 13 is a longitudinal sectional view of the semiconductor substrate 12 in which trenches 34 have been formed; and

FIG. 14 is a longitudinal sectional view of the semiconductor substrate 12 into which n-type ions are being implanted.

### DETAILED DESCRIPTION

### Embodiment 1

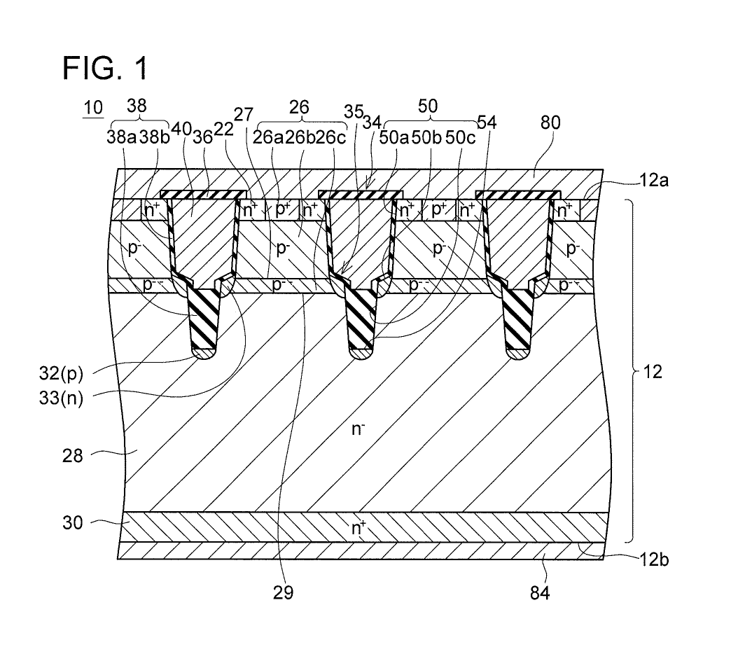

As shown in FIG. 1, a semiconductor device 10 according to Embodiment 1 includes a semiconductor substrate 12 and electrodes, insulating layers, and the like located on a front surface 12a and/or a back surface 12b of the semiconductor substrate 12. The semiconductor substrate 12 is made of 4H—SiC.

A source electrode 80 is located on the front surface 12a of the semiconductor substrate 12. A drain electrode 84 is located on the back surface 12b of the semiconductor substrate 12. The drain electrode 84 covers substantially a whole area of the back surface 12b.

Each trench 34 has a side surface 50. A step 35 is formed in the side surface 50 of the each trench 34. The side surface 50 of the each trench 34 includes an upper side surface 50a located on an upper side with respect to the step 35, a step surface 50b which is a surface of the step 35, and a lower side surface 50c located on a lower side with respect to the step 35. The step surface 50b of the step 35 slopes downward as it extends toward a center of the trench 34 in a width direction. That is, portions of the step surface 50b of step 35 formed in the side surface 50 on both sides of the trench 34 slope in a tapered shape. The upper side surface 50a and the lower side surface 50c extend substantially along a thickness direction of the semiconductor substrate 12, although the upper side surface 50a and the lower side surface 50c slightly slope in a tapered shape.

A gate insulating layer 38 and a gate electrode 40 are located in each trench 34. The gate insulating layer 38 includes a bottom insulating layer 38a and a side insulating layer 38b. The bottom insulating layer 38a is a thick insulating layer located in a bottom part of the trench 34. The bottom insulating layer 38a is located in a portion of the trench 34 that is located on the lower side with respect to the step 35. A portion of the side surface 50 of the trench 34 that is located on an upper side of the bottom insulating layer 38a is covered with a side insulating film 38b. That is, the side insulating film 38b covers the upper side surface 50a and the step surface 50b of the step 35. The side insulating film 38b is connected to the bottom insulating layer 38a. The gate electrode 40 is located in a portion of the trench 34 that is located on the upper side of the bottom insulating layer 38a. The gate electrode 40 is insulated from the semiconductor substrate 12 by the side insulating film 38b and the bottom insulating layer 38a. An upper surface of the gate electrode 40 is covered with an interlayer insulating layer 36. The gate electrode 40 is insulated from the source electrode 80 by the interlayer insulating layer 36.

In the semiconductor substrate 12, source regions 22, a body region 26, a drift region 28, a drain region 30, bottom regions 32, and side regions 33 are provided.

A plurality of the source regions 22 are formed in the semiconductor substrate 12. Each of the source regions 22 is an n-type region. The source region 22 is provided at a position adjacent to each trench 34. The source region 22 is in contact with the side insulating film 38b at the upper side surface 50a of the trench 34. The source region 22 is provided in a range exposed on the surface 12a of the semiconductor substrate 12. The source region 22 is in ohmic contact with the source electrode 80.

The body region 26 is provided on lateral and lower sides of the source region 22, and is in contact with the source regions 22. The body region 26 is a p-type region, and includes a high-concentration region 26a, an upper region 26b, and a lower region 26c. The high-concentration region 26a has a higher p-type impurity concentration than those of the upper region 26b and the lower region 26c. The high-concentration region 26a is provided on the lateral sides of the source regions 22 and exposed on the surface 12a of the semiconductor substrate 12. The high-concentration region 26a is in ohmic contact with the source electrode 80. The upper region 26b is provided on the lower sides of the source regions 22 and the high-concentration region 26a. The upper region 26b is in contact with the side insulating films 38b at a portion of the upper side surface 50a of the trench 34 that is located on the lower sides of the source regions 22. The p-type impurity concentration of the upper region 26b is lower than that of the high-concentration region 26a. The p-type impurity concentration of the upper region 26b is adjusted to be such a concentration that a portion of the upper region 26b that is located near the side insulating layers 38b can be inverted into an n-type when a potential of the gate electrode 40 is raised. The lower region 26c is provided on a lower side of the upper region 26b. The p-type impurity concentration of the lower region 26c is lower than that of the upper region 26b. A boundary 27 between the lower region 26c and the upper region 26b is located at a depth of the step 35. That is, an extension line of the boundary 27 that extends toward each trench 34 intersects with the step 35.

The drift region 28 is an n-type region containing a low concentration of n-type impurities. The n-type impurity concentration of the drift region 28 is lower than that of the source regions 22. The drift region 28 is provided on a lower side of the lower region 26c, and is in contact with the lower region 26c. The drift region 28 spreads from a position at a lower end of the lower region 26c to a position lower than a lower end of the trench 34. The drift region 28 is separated from the source regions 22 by the body region 26. The drift region 28 is in contact with the bottom insulating layers 38a at the lower side surfaces 50c.

Each side region 33 is an n-type region. The side region 33 is provided on the lower side of the step 35. The side region 33 is provided in a range exposed on the step surface 50b of the step 35 and a portion of the lower side surface 50c that is located near the step 35. The side region 33 is in contact with the side insulating film 38b in a whole area of the step surface 50b of the step 35. Further, the side region 33 is in contact with the bottom insulating layer 38a at a portion of the lower side surface 50c that is located near the step 35. The side region 33 extends downward from the step surface 50b of the step 35. The side region 33 is in contact with the upper region 26b and the lower region 26c. Further, the side region 33 has its lower end part connected to the drift region 28.

The aforementioned source regions 22, the aforementioned upper region 26b, and the aforementioned side regions 33 face the respective gate electrodes 40 via the respective side insulating films 38b.

Each bottom region 32 is a p-type region. The bottom region 32 is provided at a position exposed on a bottom surface 54 of each trench 34. The bottom region 32 is in contact with the bottom insulating layer 38a in a whole area of the bottom surface 54 of the trench 34. The bottom region 32 is surrounded by the drift region 28. The bottom region 32 is separated from the body region 26 and the side region 33 by the drift region 28. The bottom region 32 is connected to none of the electrodes, and a potential of the bottom region 32 is a floating potential.

The drain region 30 is an n-type region containing a high concentration of n-type impurities. The n-type impurity concentration of the drain region 30 is higher than that of the drift region 28. The drain region 30 is provided on a lower side of the drift region 28. The drain region 30 is in contact with the drift region 28, and is separated from the body region 26, the bottom regions 32, and the side regions 33 by the drift region 28. The drain region 30 is provided in a range exposed on the back surface 12b of the semiconductor substrate 12. The drain region 30 is in ohmic contact with the drain electrode 84.

Next, an operation of the semiconductor device 10 will be described. In the semiconductor substrate 12, a MOSFET of an n-channel type is provided by the source regions 22, the body region 26, the drift region 28, the side regions 33, the drain region 30, the gate electrodes 40, the gate insulating layers 38, and the like. In order for the semiconductor device 10 to operate, a higher potential is applied to the drain electrode 84 than a potential applied to the source electrode 80. Furthermore, application of a potential equal to or higher than a threshold value to the gate electrode 40 causes the MOSFET to be turned on. That is, a channel is formed in a portion (i.e. the upper region 26b) of the body region 26 located in a range being in contact with the side insulating films 38b. This causes electrons to flow from the source electrode 80 toward the drain electrode 84 through the source regions 22, the channel, the side regions 33, the drift region 28, and the drain region 30.

In this semiconductor device 10, the side regions 33, which protrude toward an upper side with respect to the drift region 28, are provided in positions being in contact with the side insulating layers 38b. The channel that is formed in the body region 26 connects the source regions 22 and the side regions 33. That is, a distance between the source regions 22 and the side regions 33 corresponds to a length of the channel. The provision of the side regions 33 causes the channel length to be shorter than a thickness of the body region 26 between the drift region 28 and the source regions 22. For this reason, this semiconductor device 10 has a smaller loss in the channel than a conventional semiconductor device does.

When the potential of the gate electrode 40 is reduced to a potential lower than the threshold value, the channel disappears, thus causing the MOSFET to be turned off. This causes a depletion layer to spread into the body region 26 and the drift region 28 from a p-n junction 29 at a boundary between the body region 26 and the drift region 28. The depletion layer, which extends from the p-n junction 29 into the drift region 28, reaches the bottom regions 32. Then, the depletion layer spreads from the bottom regions 32 into a portion of the drift region 28 that is located around the bottom regions 32. That is, the bottom regions 32 facilitate the extension of the depletion layer into the drift region 28. After that, the depletion layer extends over a substantial whole area of the drift region 28. Since the extension of the depletion layer is thus facilitated by the bottom regions 32, generation of a high electric field near the gate insulating layers 38 is prevented. This improves a withstand voltage characteristics of the semiconductor device 10.

Further, under normal use, the depletion layer, which extends from the p-n junction 29 into the body region 26, does not reach the source region 22. That is, the extension of the depletion layer, which extends from the p-n junction 29 into the body region 26, stops in a state where the depletion layer has its upper end located within the upper region 26b. However, depending on an operation state of a circuit to which the semiconductor device 10 is connected, a potential of the drain electrode 84 may become extremely high. Application of such an extremely high potential to the drain electrode 84 may cause the depletion layer, which extends from the p-n junction 29 into the body region 26, to reach the source region 22. That is, a punch-through occurs. The semiconductor device 10 according to the present embodiment has a high punch-through voltage, as the distance from the drift region 28 to the source region 22 (i.e. the distance from the p-n junction 29 to the source region 22) is sufficiently long. This makes it difficult for the punch-through to occur in the semiconductor device 10.

In the semiconductor device 10 according to the present embodiment, as described above, the thickness of the body region 26 is sufficiently great, thereby ensuring a sufficient distance from the drift region 28 to the source region 22. This achieves a high punch-through voltage. Further, in the semiconductor device 10, the n-type side regions 33, which protrude upward from the drift region 28, are provided in a position being in contact with the side insulating layer 38b. For this reason, the channel length (i.e. the distance from the source region 22 to the side regions 33) is short although the thickness of the body region 26 is great. This achieves a reduction in loss in the semiconductor device 10. In this way, this structure of this semiconductor device 10 makes it possible to independently adjust the punch-through voltage and the channel length. This allows for both a high punch-through voltage and the reduction in loss in the channel.

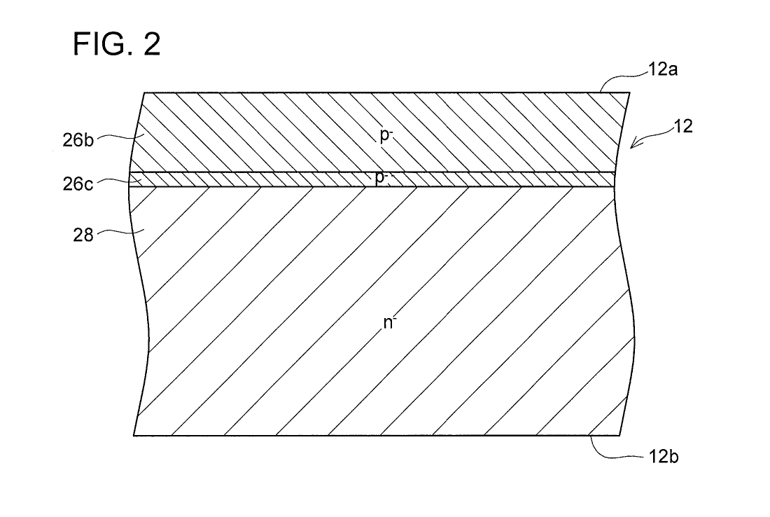

Next, a method for manufacturing a semiconductor device 10 will be described. The semiconductor device 10 is manufactured from an n-type semiconductor substrate 12 entirely having substantially the same n-type impurity concentration as that of a drift region 28. First, by ion implantation of p-type impurities, as shown in FIG. 2, a lower region 26c and an upper region 26b are formed in the semiconductor substrate 12. The lower region 26c is formed to be located on and above the drift region 28. The upper region 26b is formed to be located on and above the lower region 26c. The upper region 26b has a higher p-type impurity concentration than that of the lower region 26c. At this stage, the upper region 26b is exposed on a surface 12a of the semiconductor substrate 12.

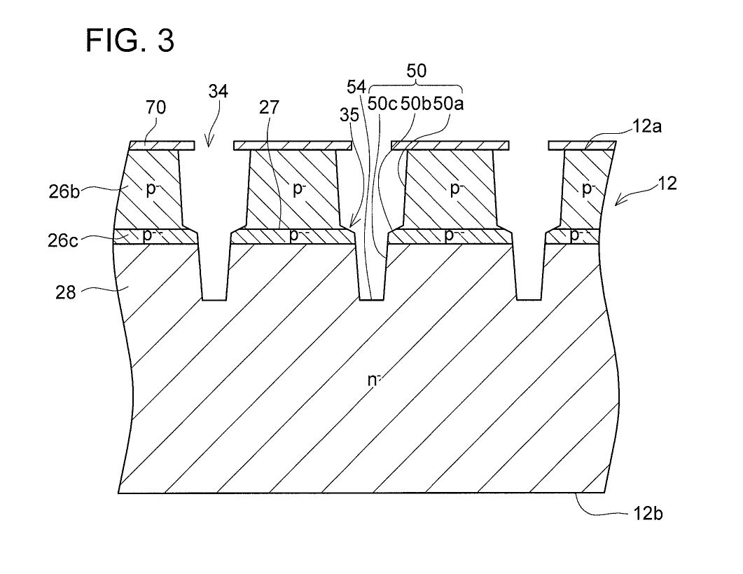

Next, as shown in FIG. 3, an etching mask 70 is formed on the surface 12a of the semiconductor substrate 12, and the semiconductor substrate 12 is etched through the etching mask 70. At this stage, the semiconductor substrate 12 is etched by anisotropic dry etching. This causes trenches 34 to be formed in the surface 12a of the semiconductor substrate 12. It should be noted that the p-type impurity concentration of the upper region 26b is higher than that of the lower region 26c. For this reason, an etching rate in the upper region 26b is higher than that in the lower region 26c. In other words, the upper region 26b is etched at a higher speed than the lower region 26c. For this reason, as shown in FIG. 3, the formation of the trenches 34 that reach the drift region 28 causes a width of each trench 34 in the upper region 26b to be greater than a width of each trench 34 in the lower region 26c. As a result, a step 35 is formed in a side surface of each trench 34 at a depth of a boundary 27 between the upper region 26b and the lower region 26c. In this way, this method allows a trench 34 having a step 35 in its side surface 50 to be formed by utilizing the difference in etching rate between the upper region 26b and the lower region 26c that is caused by the difference in impurity concentration. This method allows the trenches 34 each having the step 35 to be formed in a single etching process. Further, this method allows the step surface 50b of the step 35 to be formed in a shape that slopes downward as it extends toward a center of the trench 34. Once the etching is completed, the etching mask 70 is removed.

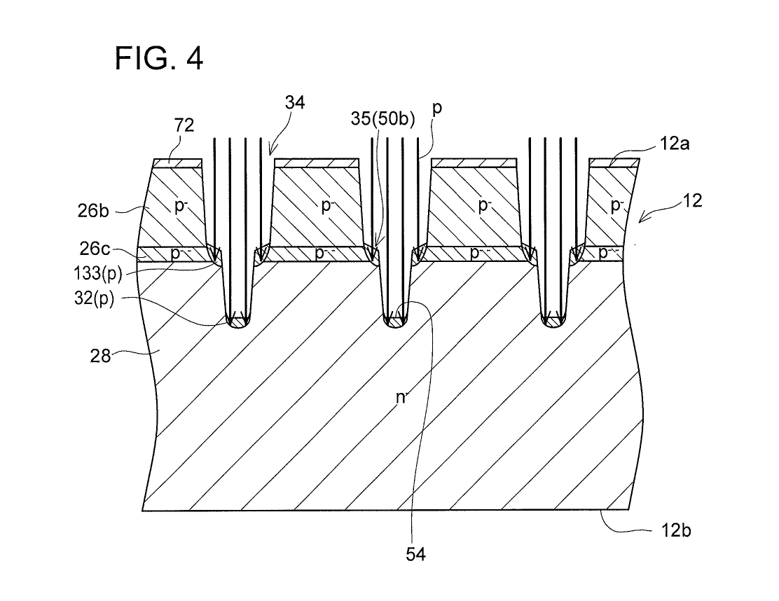

Next, as shown in FIG. 4, an ion implantation mask 72 is formed on the surface 12a of the semiconductor substrate 12, and p-type impurities are implanted into the semiconductor substrate 12 through the ion implantation mask 72. At this stage, the p-type impurities are implanted into the trenches 34. The p-type impurities are implanted into a bottom surface 54 of each trench 34 and the step surface 50b of each step 35. This causes a bottom region 32 of a p-type to be formed in a range exposed on the bottom surface 54. Further, a side region 133 of the p-type is formed in a range exposed on the step surface 50b of the step 35. Once the ion implantation is completed, the ion implantation mask 72 is removed.

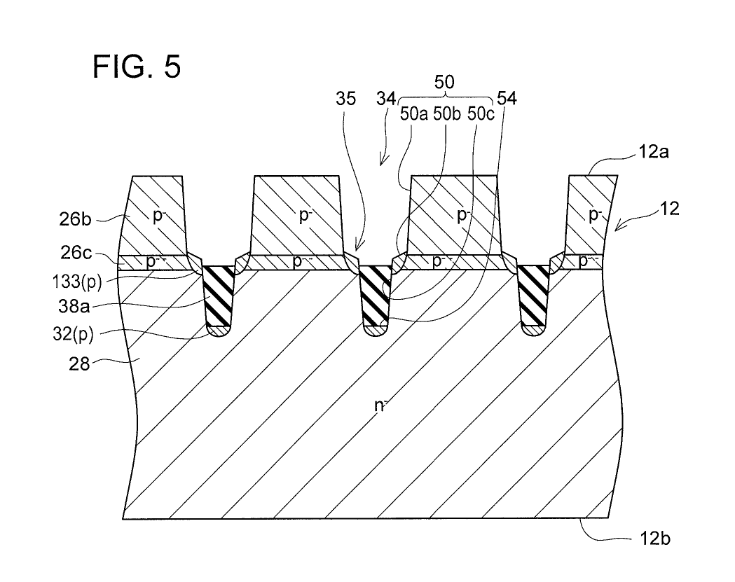

Next, an insulating layer is allowed to grow in the trenches 34 and on the semiconductor substrate 12. The insulating layer is formed in the trench 34, solidly with no space left. Next, the insulating layer is etched so that a portion of the insulating layer that is located on the semiconductor substrate 12 is removed and a portion of the insulating layer that is located in the trenches 34 is partially removed. At this stage, as shown in FIG. 5, only portions of the insulating layer that are located on a lower side with respect to the steps 35 are allowed to remain. The remaining portions of the insulating layer serve as bottom insulating layers 38a.

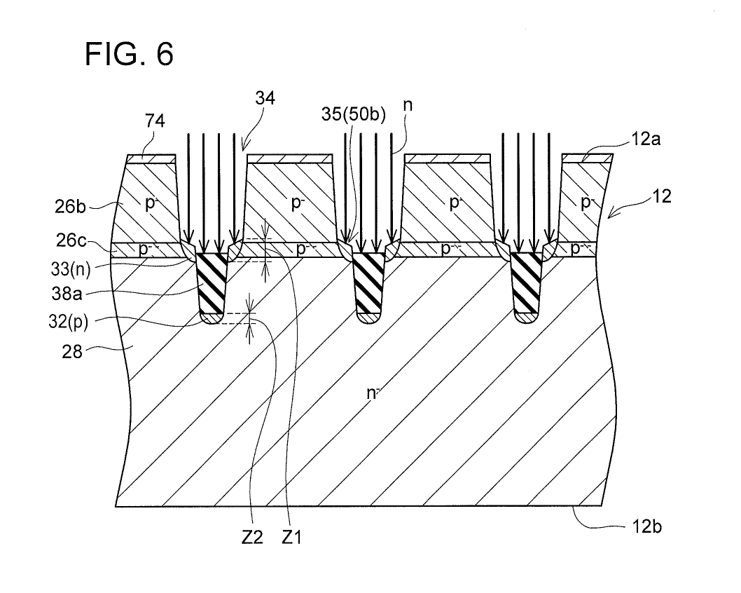

Next, as shown in FIG. 6, an ion implantation mask 74 is formed on the surface 12a of the semiconductor substrate 12, and n-type impurities are implanted into the semiconductor substrate 12 through the ion implantation mask 74. At this stage, the n-type impurities are implanted into the trenches 34. Since the bottom insulating layers 38a have been formed in portions of the trenches 34 that are located on a lower side with respect to the steps 35, the n-type impurities are not implanted into the bottom surfaces 54 of the trenches 34. At this stage, the n-type impurities are implanted into the step surfaces 50b of the steps 35. The n-type impurities are implanted into the step surfaces 50b of the steps 35 at a higher concentration than that of the p-type impurities described with reference to FIG. 4. This causes semiconductor regions exposed on the step surfaces 50b of the steps 35 to be turned into an n-type. This forms side regions 33 of an n-type. Each side region 33 has its lower end connected to the drift region 28. Further, as mentioned above, the step surface 50b of each step 35 slopes downward as it extends toward the center of the trench 34. Since the step surface 50b of the step 35 slopes in this manner, forming of a side region 33 by implanting the n-type impurities into the step surface 50b of each step 35 makes it possible to increase a width Z1 of the side region 33 in a vertical direction (i.e. a thickness direction of the semiconductor substrate 12). For this reason, the width Z1 of each side region 33 in the vertical direction is greater than a width Z2 of each bottom region 32 in the vertical direction. Once the ion implantation is completed, the ion implantation mask 74 is removed.

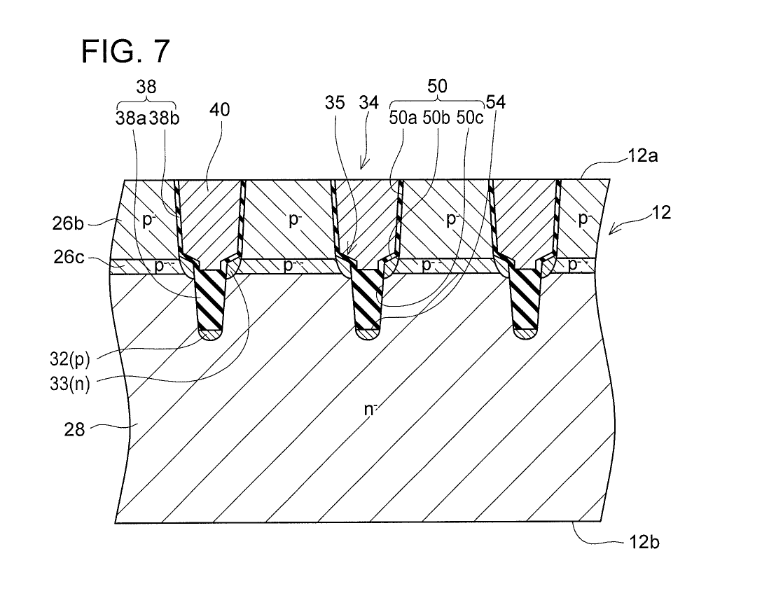

Next, as shown in FIG. 7, a side insulating film 38b is allowed to grow on a portion of the side surface 50 of e trench 34 that is located on an upper side with respect to the bottom insulating layer 38a. Once the side insulating film 38b is formed, a gate electrode 40 is formed in each trench 34 as shown in FIG. 7.

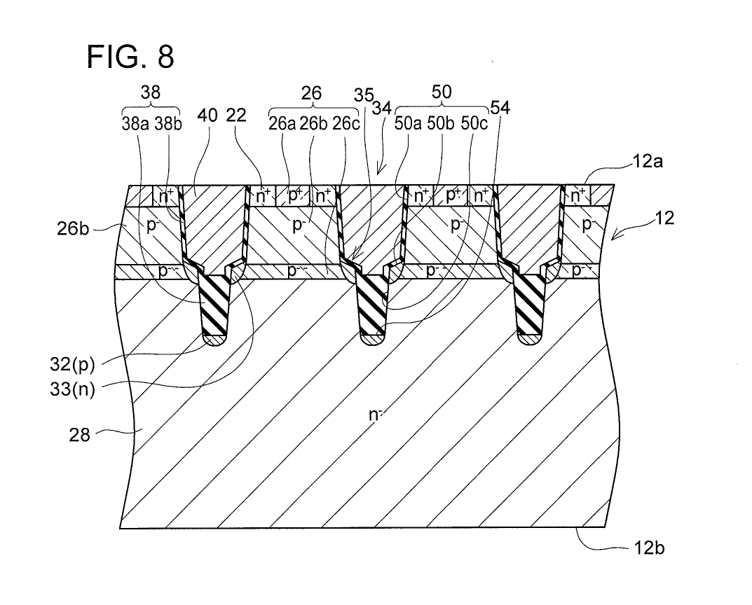

Once the gate electrodes 40 are formed, source regions 22 and a high-concentration region 26a of the body region 26 are formed as shown in FIG. 8 by selectively implanting p-type and n-type impurities into the surface 12a of the semiconductor substrate 12. Next, interlayer insulating layers 36 and a source electrode 80 are formed on the surface 12a of the semiconductor substrate 12. Next, a drain region 30 is formed by implanting n-type impurities into a back surface 12b of the semiconductor substrate 12. Next, a drain electrode 84 is formed on the back surface 12b of the semiconductor substrate 12. Through these process steps, a semiconductor device 10 shown in FIG. 1 is manufactured.

As described above, this method allows a trench 34 having a step 35 to be formed with a single etching process. This makes it possible to efficiently manufacture the semiconductor device 10.

Further, this method allows the step surface 50b of the step 35 to be formed in a shape that slopes downward as it extends toward the center of the trench 34. Therefore, the side region 33 having the great width Z1 in the vertical direction can be formed by implanting n-type impurities into the step surface 50b of the step 35. The great width Z1 of the side region 33 in the vertical direction allows the side region 33 to greatly protrude toward an upper side with respect to the drift region 28. This makes it possible to make the channel length shorter.

### Embodiment 2

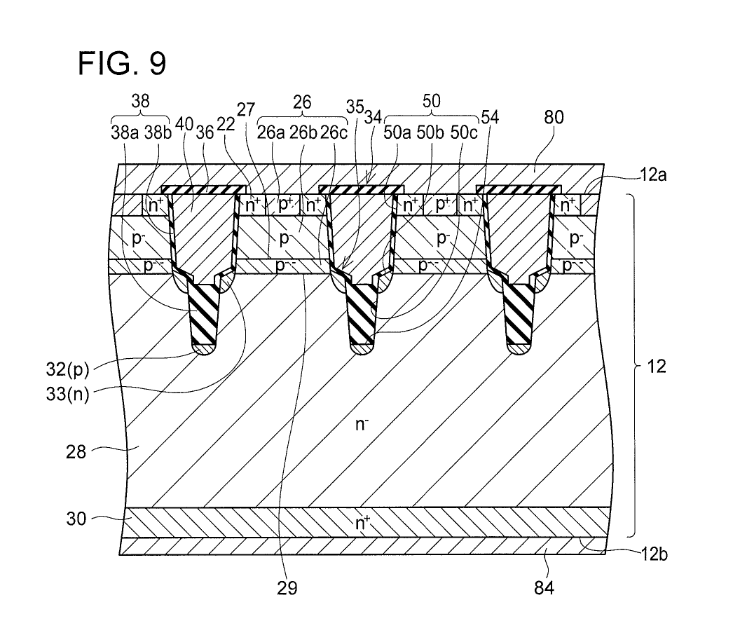

As shown in FIG. 9, a semiconductor device according to Embodiment 2 has steps 35 located at a level lower than a level of the boundary 27 between the upper region 26b and the lower region 26c. The steps 35 are located on an upper side with respect to the p-n junction 29 at a boundary between the lower region 26c and the drift region 28. The other components of the semiconductor device of Embodiment 2 are identical to those of the semiconductor device 10 of Embodiment 1. Also in the semiconductor device according to Embodiment 2, the side regions 33 protrude toward an upper side with respect to the drift region 28. This makes it possible to achieve compatibility between the channel length and the punch-through voltage. Further, by taking a longer etching time to form the trenches 34 than in Embodiment 1, the steps 35 can be located at the level lower than the level of the boundary 27 between the upper region 26b and the lower region 26c as in Embodiment 2.

### Embodiment 3

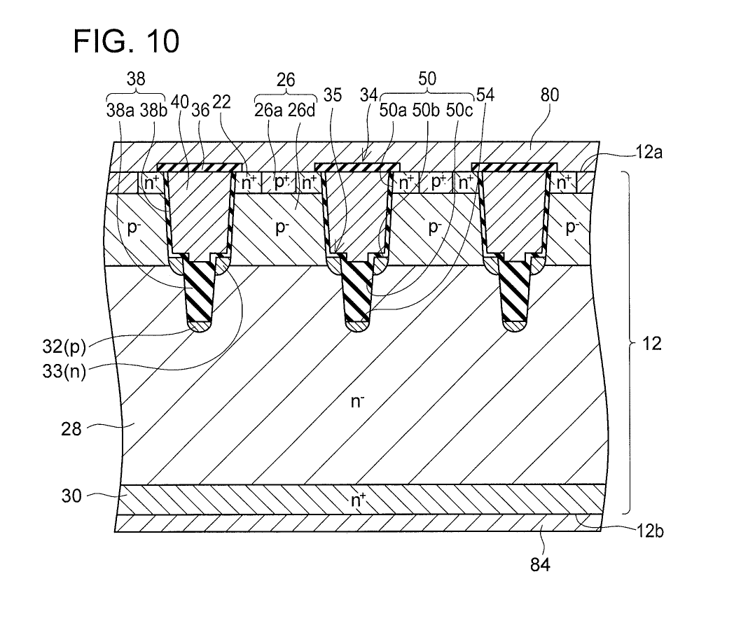

As shown in FIG. 10, a semiconductor device according to Embodiment 3 has steps 35 that do not slope. That is, the steps 35 are formed substantially parallel to the surface 12a of the semiconductor substrate 12. Further, in the semiconductor device according to Embodiment 3, the body region 26, on a lower side with respect to the high-concentration region 26a, includes only a low-concentration region 26d. That is, whereas the body region 26 includes the upper region 26b and the lower region 26c on the lower side with respect to the high-concentration region 26a in Embodiment 1, a p-type impurity concentration in a portion (i.e. the low-concentration region 26d) of the body region 26 that is located on the lower side with respect to the high-concentration region 26a is substantially uniform. The p-type impurity concentration of the low-concentration region 26d is lower than that of the high-concentration region 26a. Also in the semiconductor device according to Embodiment 3, the side region 33 protrudes toward an upper side with respect to the drift region 28. This makes it possible to achieve the compatibility between the channel length and the punch-through voltage.

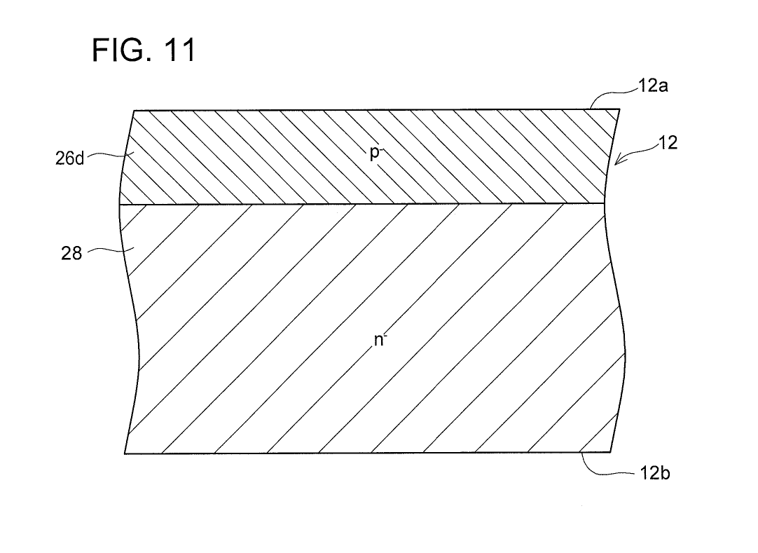

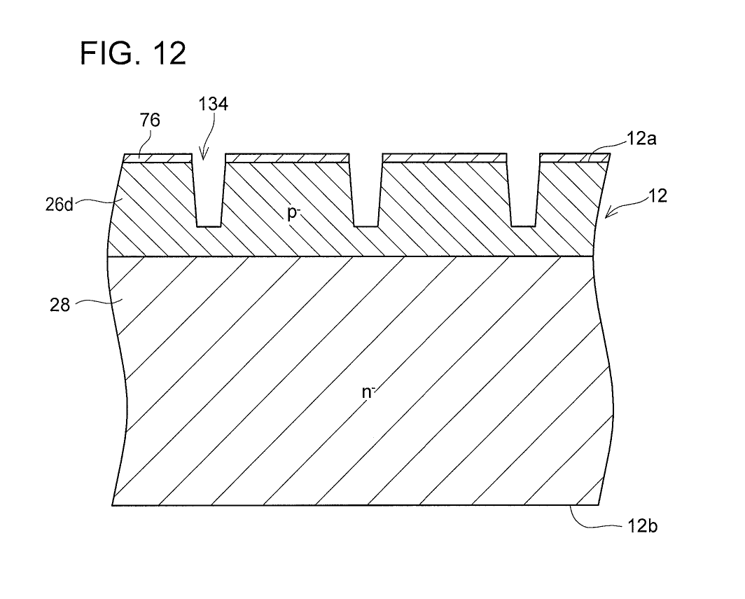

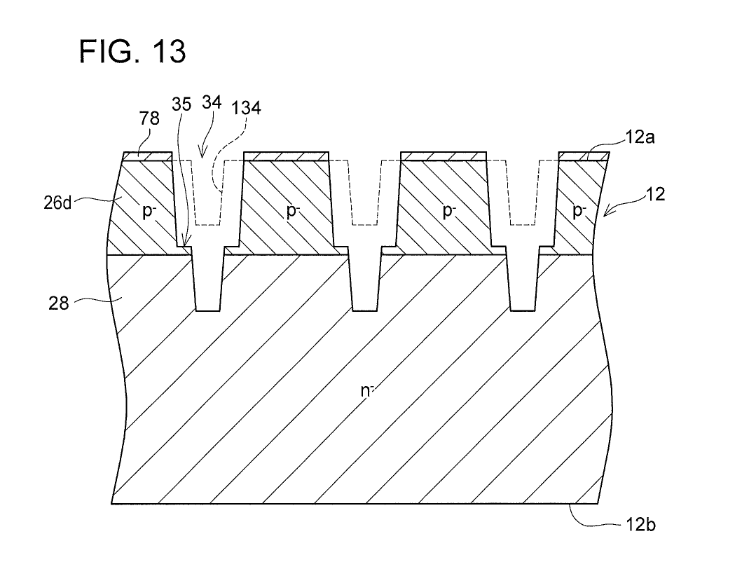

In a process of manufacturing a semiconductor device according to Embodiment 3, first, as shown in FIG. 11, a low-concentration region 26d is formed in a semiconductor substrate 12 by ion implantation of p-type impurities. Next, as shown in FIG. 12, an etching mask 76 is formed on a surface 12a of the semiconductor substrate 12, and the semiconductor substrate 12 is etched through the etching mask 76. At this stage, trenches 134 are formed. Each trench 134 is shallower than the trench 34 shown in FIG. 10. Each trench 134 is narrower in width than the trench 34. After the trenches 134 have been formed, the etching mask 76 is removed. Next, as shown in FIG. 13, an etching mask 78 is formed. The etching mask 78 has openings each of which is wider than the trench 134. Then, the semiconductor substrate 12 is etched through the etching mask 78. By thus performing the etching at two steps, trenches 34 each having a flat step 35 can be formed as shown in FIG. 13, At this stage, the trenches 34 are formed so that the steps 35 are located on an upper side with respect to the lower end of the low-concentration region 26d. After that, a semiconductor device shown in FIG. 10 can be obtained by processing the semiconductor substrate 12 in the same manner as in Embodiment 1.

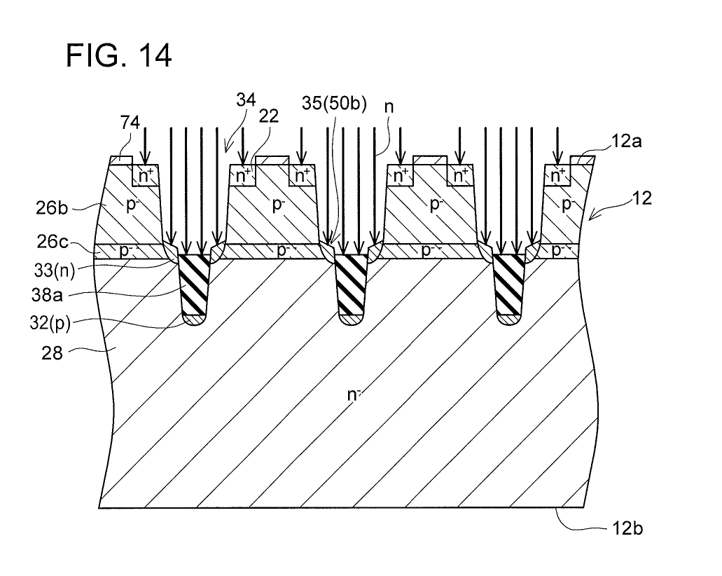

In the implantation of the n-type impurities into the steps 35 according to each of the embodiments described above, as shown in FIG. 14, each of the openings in the mask 74 may be formed to be wider than the trench 34 and the n-type impurities may also be implanted into portions of a surface 12a of the semiconductor substrate 12 that are adjacent to the respective trenches 34. This makes it possible to form the source regions 22 at the same time as the side regions 33.

Further, in each of the embodiments described above, the potential of each bottom region 32 is a floating potential. However, the bottom region 32 may be connected to a predetermined fixed potential.

Further, in each of the embodiments described above, a MOSFET of an re-channel type has been described. However, the technology disclosed herein may be applied to a MOSFET of a p-channel type.

Further, the bottom insulating layers 38a may have its upper ends located on a lower side with respect to the p-n junction 29, although the bottom insulating layers 38a has its upper ends located on an upper side with respect to the p-n junction 29 in Embodiment 1.

Correspondence between the components of each of the embodiments described above and the components of the claims is described. The source region 22 of each of the embodiments is an example of the first region of the claims. The drift region 28 of each of the embodiments is an example of the second region of the claims.

Some of the following enumerates the technical elements disclosed herein. It should be noted that the following technical elements are useful independently of one another.

In a configuration disclosed herein as an example, the step surface may slope downward as it extends toward a center of the trench.

Such a configuration makes it possible to increase the width of the side region in the vertical direction. This makes it possible to further improve the trade-off relationship between the channel length and the punch-through voltage.

In a configuration disclosed herein as an example, the body region may include an upper region and a lower region. The lower region is located on a lower side of the upper region. A concentration of impurities of the second conductivity type in the lower region is lower than that in the upper region. The step is located at a level equal to or lower than a level of a boundary between the upper region and the lower region.

Such a configuration allows a trench having a step to be formed in a single etching process by utilizing the difference in etching rate between the upper region and the lower region.

In a configuration of a method disclosed herein as an example, the body region may include a lower region located on the upper side of the second region and an upper region located on an upper side of the lower region. A concentration of impurities of the second conductivity type in the upper region is higher than that in the lower region. In the formation of the trench, the semiconductor substrate is etched so as to form the trench penetrating the upper region and the lower region and reaching the second region.

Such a configuration allows a trench having a step to be formed in a single etching process by utilizing the difference in etching rate between the upper region and the lower region.

In a configuration of a method disclosed herein as an example, impurities of the second conductivity type may be implanted to a bottom surface of the trench so as to form a bottom region being of the second conductivity type and exposed on the bottom surface. The formation of the gate insulating layer comprises a formation of a bottom insulating layer and a formation of a side insulating layer. The bottom insulating layer is formed in a portion of the trench that is located on a lower side with respect to the step, after the implantation of the impurities of the second conductivity type and before the implantation of the impurities of the first conductivity type. The side insulating layer is formed on a portion of the side surface that is located on an upper side with respect to the bottom insulating layer after the implantation of the impurities of the first conductivity type.

In a configuration of method disclosed herein as an example, in the implantation of the impurities of the first conductivity type, the impurities of the first conductivity type may be implanted to a surface of the semiconductor substrate that is adjacent to the trench.

Such a configuration makes it possible to implant the impurities of the first conductivity type into the first region while implanting the impurities of the first conductivity type into the side region.

The embodiments have been described in detail in the above. However, these are only examples and do not limit the claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

What is claimed is:

1. A semiconductor device comprising:
a semiconductor substrate that comprises a surface and a trench in the surface ;
a gate insulating layer covering an inner surface of the trench; and
a gate electrode located in the trench,
wherein
a step is arranged in a side surface of the trench;
the side surface of the trench includes an upper side surface located on an upper side with respect to the step, a step surface which is a surface of the step, and a lower side surface located on a lower side with respect to the step,
the semiconductor substrate comprises:
a first region being of a first conductivity type and in contact with the gate insulating layer at the upper side surface;
a body region being of a second conductivity type, extending from a position being in contact with the first region to a position located on the lower side with respect to the step, and being in contact with the gate insulating layer at a portion of the upper side surface that is located on a lower side with respect to the first region;
a second region being of the first conductivity type, located on a lower side of the body region, and being in contact with the gate insulating layer at the lower side surface; and
a side region being of the first conductivity type, being in contact with the gate insulating layer at the step surface, and connected to the second region.

2. The semiconductor substrate of claim 1, wherein the step surface slopes downward as it extends toward a center of the trench.

3. The semiconductor substrate of claim 1, wherein
the body region includes an upper region and a lower region,
the lower region is located on a lower side of the upper region,
a concentration of impurities of the second conductivity type in the lower region is lower than that in the upper region, and
the step is located at a level equal to or lower than a level of a boundary between the upper region and the lower region.

4. A method for manufacturing a semiconductor device, the method comprising:
preparing a semiconductor substrate that comprises a second region being of a first conductivity type, and a body region being of a second conductivity type and located on an upper side of the second region;
forming a trench in the semiconductor substrate such that the trench penetrates the body region so as to reach the second region and includes a side surface in which a step is formed at a position located on an upper side with respect to the second region;
implanting impurities of the first conductivity type to a step surface which is a surface of the step so as to form a side region being of the first conductivity type, exposed on the step surface, and connected to the second region;
forming a gate insulating layer covering an inner surface of the trench;
forming a gate electrode in the trench; and
forming a first region being of the first conductivity type in the semiconductor substrate,
wherein, in the manufactured semiconductor device, the first region is in contact with the gate insulating layer at a portion of the side surface that is located on an upper side with respect to the step.

5. The method of claim 4, wherein
the body region includes a lower region located on the upper side of the second region and an upper region located on an upper side of the lower region,
a concentration of impurities of the second conductivity type in the upper region is higher than that in the lower region, and
in the formation of the trench, the semiconductor substrate is etched so as to form the trench penetrating the upper region and the lower region and reaching the second region.

6. The method of claim 4, further comprising:
implanting impurities of the second conductivity type to a bottom surface of the trench so as to form a bottom region being of the second conductivity type and exposed on the bottom surface,
wherein the formation of the gate insulating layer comprises:
forming a bottom insulating layer in a portion of the trench that is located on a lower side with respect to the step, after the implantation of the impurities of the second conductivity type and before the implantation of the impurities of the first conductivity type; and
forming a side insulating layer on a portion of the side surface located on an upper side with respect to the bottom insulating layer after the implantation of the impurities of the first conductivity type.

7. The method of claim 4, wherein, in the implantation of the impurities of the first conductivity type, the impurities of the first conductivity type are implanted to a surface of the semiconductor substrate that is adjacent to the trench.
